(19) United States
(12) Patent Application Publication
(10) Pub. No.: US 2009/0237093 A1
(43) Pub. Date: Sep. 24, 2009

(54) MICROWAVE RECTENNA BASED SENSOR ARRAY FOR MONITORING PLANARITY OF STRUCTURES

(75) Inventors: Jae-Hwan Kim, Incheon (KR); Sang-Hyouk Choi, Poquoson, VA (US); Kyo-Dong Song, Yorktown, VA (US)

Correspondence Address: TUROCY & WATSON, LLP, 127 Public Square, 57th Floor, Key Tower, CLEVELAND, OH, 44114, US

(73) Assignee: INHA-INDUSTRY PARTNERSHIP INSTITUTE, Nam-gu, Incheon (KR)

(21) Appl. No.: 12/294,048

(22) PCT Filed: May 23, 2006
(86) PCT No.: PCT/KR06/01936

§ 371 Date: Sep. 23, 2008

(30) Foreign Application Priority Data
Mar. 30, 2006 (KR) 10-2006-0028997

(51) Int. Cl. G01R 29/00; G01B 21/00

(52) U.S. Cl. 324/637

(57) ABSTRACT

A microwave rectenna based sensor array is disclosed, which can remotely detect and monitor the planarity and curvature change of the surface of a structure, irrespective of the size or shape of the structure, by using a microwave signal.

### TECHNICAL FIELD

The present invention relates to a microwave rectenna based sensor array for monitoring the planarity of strictures.

### BACKGROUND ART

For the shape control or shape deformation of structures, it is required to accurately measure and detect size variation of the structures with respect to the shape change or shape deformation. For this, laser scanning and optical monitoring methods have been conventionally used in the art.

However, the conventional laser scanning method cannot instantaneously capture an infinitesimal modification of the structure because it takes a lot of time to scan laser. Also, the conventional optical monitoring method needs a uniform surface reflection in time and space, and the monitoring for measurement is interrupted by color and temperature changes.

### DISCLOSURE OF INVENTION

### Technical Problem

Therefore, the present invention has been made in view of the above-mentioned problems.

An object of the present invention is to accurately monitor and measure the shape change of a large-sized structure, and particularly, of the surface thereof.

### Technical Solution

In embodiments of the present invention, all shape changes of a structure can be detected and measured, and the measurement and monitoring can be carried out without any time delay, irrespective of differences in optical properties and changes in color or temperature. A rectenna designed for high-frequency microwaves is composed of a thin film flexible patch having a micron thickness and a small size. The patch rectenna converts a microwave power into a DC power, and the converted DC power is inverted by a rectifier circuit, thereby generating reradiating microwaves, which is very similar to optical reflection. The inverse mode of the rectenna does not require any additional drive power. The reradiated microwave signal is monitored by a reception antenna so as to reconstruct the shape image of the structure. If the sensor array thin film layer of the present invention attached to the surface of the structure is distorted due to the surface distortion of the structure, its output signal pattern and intensity are changed. The shape deformation of an object can be detected by the output signal change. A single or array sensor (which is packed densely or sparsely) may be used as a sensor for detecting the shape deformation.

In one aspect of the present invention, there is provided a flexible thin film sensor array that can be easily and flexibly attached to any shape of a structure to be monitored.

In another aspect of the present invention, there is provided a sensor that can be implemented as a single-element or multi-element member.

In still another aspect of the present invention, there is provided a sensor that can provide a stable and clear sensed signal, irrespective of color change, optical de-formation, and temperature change of a structure to be monitored.

In still another aspect of the present invention, there is provided a sensor that uses an inverse mode of a rectenna and thus requires no drive power.

In still another aspect of the present invention, there is provided a simple and in-expensive apparatus for monitoring the shape deformation.

### ADVANTAGEOUS EFFECTS

According to an embodiment of the present invention as constructed above, the minute shape change of any type structures, and particularly, the surface deformation thereof, can be accurately monitored and measured.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is an exemplary view illustrating a rectenna rectifier circuit having a normal mode and an inverse mode;

FIG. 2 is al exemplary view illustrating the structure of a patch-type rectenna sensor array integrally with a flexible membrane;

FIG. 3 is an exemplary view illustrating the microwave reaction of respective components of a sensor array; and

FIG. 4 is an exemplary view illustrating a system for measuring the planarity of a structure using a sensor array.

### BEST MODE FOR CARRYING OUT THE INVENTION

Reference will now be made in detail to the preferred embodiments of the present invention. It is to be understood that the following examples are illustrative only and the present invention is not limited thereto.

The present invention is based on a microwave patch-type rectenna driven in a normal mode or an inverse mode. The mode switching of the patch rectenna is identical to that of the dipole antenna shown in FIG. 1. The microwave power received by the patch rectenna is rectified into a DC power by a rectifier circuit which is configured by a Schottky barrier diode having a low-pass filter. However, the AC power is inversely supplied to the circuit in the inverse mode, and then is modulated to generate a microwave signal. By the mode switching of the patch antenna, the microwave beams can be absorbed, and an identical or differential frequency signal is radiated according to the frequency modulation. This operates as a reflector.

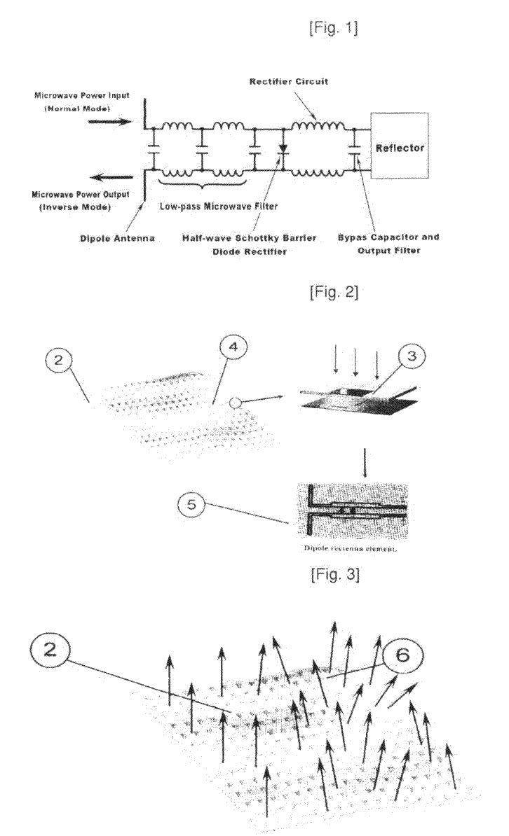

FIG. 2 is an enlarged view of an element 4 constituting a patch sensor array 2 according to the present invention, in which each rectenna element 5 is protected by a flexible membrane 3. The membrane 3 is integrally formed with the rectenna 4. A thin film metal patch becomes possible using the skin effect of a high frequency signal. An area of the patch becomes smaller, as compared with the high frequency of an apparatus. For example, if the frequency is higher than 35 GHz (Ka-band), the area of the rectenna patch becomes less than 0.25 square inch. Therefore, the patch rectenna array 2 is very thin and flexible, and can be densely or sparsely packed.

FIG. 3 shows split beam patterns 6 reradiated from a curved thin film array 2. Elements may be arranged in the form of an array densely or sparsely packed. For example, in the case where a wide area is curved in such a way that respective elements do not experience any shape change, the beam directions in the respective elements are altered due to the non-orientation of the elements in the sensor array 2. The microwave reradiated by the curved planar array sensor determines a curved pattern of the structure through a spatial splitting image structure process.

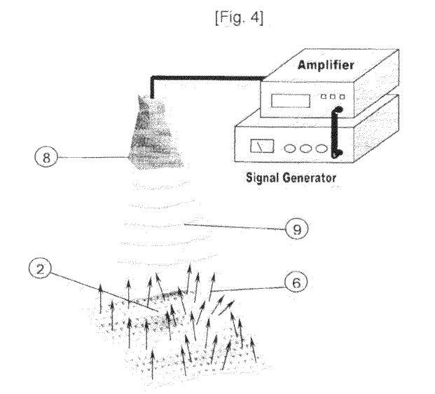

FIG. 4 illustrates a system for measuring the shape change using the planar sensor element array 2. First, the planar sensor array 2 is attached to the surface of the structure. Then, a transceiver 8 irradiates a high frequency microwave signal 1. The irradiated signal pattern is picked up by the transceiver horn 8 to split the space, thereby forming a deformed image.

While this invention has been described in connection with what is presently considered to be the most practical and preferred embodiment, it is to be understood that the invention is not limited to the disclosed embodiment and the drawings. On the contrary, it is intended to cover various modifications and variations within the spirit and scope of the appended claims.

### INDUSTRIAL APPLICABILITY

As can be seen from the foregoing, according to an embodiment of the present invention, the minute shape change of any type structures, and particularly, the surface deformation thereof, can be accurately monitored and measured.

1. A microwave rectenna based sensor array for monitoring the planarity of structures, comprising a plurality of sensor elements, each of which is composed of a thin film membrane for protecting a rectenna element, wherein the rectenna element and the thin film membrane are integrated into the sensor element.

2. The microwave rectenna based sensor array as claimed in claim 1, wherein the rectenna element has a reflector for converting an input microwave signal into a power and then converting the power into a microwave signal to reradiate the microwave signal.

3. The microwave rectenna based sensor array as claimed in claim 1, wherein the rectenna based sensor array is in the form of a patch.

4. The microwave rectenna based sensor array as claimed in claim 1, further comprising a microwave transceiver horn, a frequency amplifier, and a signal generator.

5. A method for monitoring and measuring a change of a shape and/or a surface of a structure by using the microwave rectenna based sensor array according to any one of the precedent claims.
